(19) United States
(12) Patent Application Publication
(10) Pub. No.: US 2006/0103016 A1
(43) Pub. Date: May 18, 2006

(54) Heat sinking structure

(75) Inventors: Teck Tiong Tan, Singapore (SG); Hwee Seng Jimmy Chew, Singapore (SG)

Correspondence Address: CONLEY ROSE, P.C., P. O. BOX 3267, HOUSTON, TX, 77253-3267, US

(73) Assignee: Advanpack Solutions Pte Ltd, Singapore (SG)

(21) Appl. No.: 10/987,496

(22) Filed: Nov. 12, 2004

(51) Int. Cl. H01L 23/34

(52) U.S. Cl. 257/720

(57) ABSTRACT

High performance integrated circuits generally have high heat generating capabilities. During powering up of these integrated circuits under typical operating conditions, heat generation is unavoidably accelerated. When the accumulated heat is not adequately dissipated, the high temperature of the integrated circuits will lead to overheating which in turn, causes irreversible damage to the integrated circuits. Conventional thermal management methods using bumps of a ball grid array (BGA) as heat paths to a heat sink has low thermal transmissibility due to the substantially spherical shape thereof. Metallic columns formed by vias in substrates have dimensional restrictions that also limit thermal transmissibility thereof. Coupling of semiconductor device directly to a heat sink formed in a substrate will also require undesirable structural modifications to the substrate, for example a concavity formed therein, for accommodating the integrated circuit therewithin. Embodiments of the invention describe a heat sinking structure comprising: a carrier having a circuitry formed integral therewith; a substrate having a thermal conductor formed integral therewith; a heat sink thermally communicating with the thermal conductor of the substrate; and a pillar extending from the carrier to the substrate for structurally intercoupling and spatially interdisplacing the carrier and the substrate, the pillar for thermally coupling the carrier to the thermal conductor of the substrate such that heat generated by the circuitry is conveyed therefrom to the thermal conductor via the pillar, and that the thermal conductor conveys heat received thereby to the heat sink.

### FIELD OF INVENTION

The present invention relates generally to a heat sinking structure. In particular, the invention relates to a pillar connector-based heat sinking structure for dissipating heat generated by integrated circuits.

### BACKGROUND

High performance integrated circuits generally generate a considerable amount of heat. During powering up of these integrated circuits under typical operating conditions, heat generation is unavoidably accelerated. Unassisted cooling of the integrated circuits consequently leads to heat accumulation therewithin. When the accumulated heat is not adequately dissipated, the high temperature of the integrated circuits will lead to overheating which in turn, causes irreversible damage to the integrated circuits.

Conventional thermal management methods includes use of one or more bumps of a ball grid array (BGA) of an integrated circuit for conveying heat therefrom to a heat sink or a heat path formed on a substrate. However, the size of each BGA bump limits heat transmissibility between the BGA bumps and the integrated circuit. Controlling the solder content to achieve the required bump size is also metallurgically difficult.

U.S. Pat. No. 6,670,699 B2 (Mikubo) describes a semiconductor device packaging structure comprising a heat sink formed integral with the substrate. In one embodiment of Mikubo, metallic columns formed integral with the substrate function as heat links between an integrated circuit and the heat sink. However, the metallic columns are formed as vias which have to be structurally supported by the substrate. Additionally, the dimensional limitation for vias formed in a substrate restricts the heat transmissibility between the integrated circuit and the heat sink.

In another embodiment of Mikubo, the semiconductor device is coupled directly to the heat sink. However, since the heat sink is formed integral with the substrate, a concavity has to be formed in the substrate to accommodate the integrated circuit therewithin when it is coupled to the heat sink.

Hence, this clearly affirms a need for a heat sinking structure for improving heat management.

### SUMMARY

In accordance with a first aspect of the invention, there is disclosed a heat sinking structure comprising:

a carrier having a mounting face and a back face outwardly opposing the mounting face, the carrier having a circuitry formed integral therewith, and the circuitry generating heat therefrom when being operated;

a pillar extending from the carrier and being in thermal communication with the circuitry, the pillar being structurally rigid; and

a heat sink being in thermal communication with the pillar,

wherein heat generated by the circuitry is conveyed therefrom to the heat sink via the pillar.

In accordance with a second aspect of the invention, there is disclosed a heat sinking structure comprising:

a carrier having a mounting face and a back face outwardly opposing the mounting face, the carrier having a circuitry formed integral therewith, and the circuitry generating heat therefrom when being operated;

a substrate having a thermal conductor formed integral therewith;

a first heat sink being in thermal communication with the thermal conductor of the substrate; and

a first pillar extending from the mounting face of the carrier to the substrate for structurally intercoupling and spatially interdisplacing the carrier and the substrate for forming a channel therebetween, the first pillar for thermally coupling the carrier to the thermal conductor of the substrate,

wherein heat generated by the circuitry is conveyed therefrom to the thermal conductor via the first pillar, and the thermal conductor for conveying heat received thereby to the first heat sink.

### BRIEF DESCRIPTION OF THE DRAWINGS

Embodiments of the invention are described hereinafter with reference to the following drawings, in which:

FIG. 1 shows a partial front sectional view of a heat sinking structure according to a first embodiment of the invention;

FIG. 2 shows a flow diagram of a first heat path formed by the heat sinking structure of FIG. 1;

FIG. 3 shows a partial front sectional view of the heat sinking structure of FIG. 1 when implemented to a Quad-Flat No-Lead (QFN) package;

FIG. 4 shows a partial front sectional view of a heat sinking structure according to a second embodiment of the invention;

FIG. 5 shows a flow diagram of the first heat path of FIG. 2 with a second heat path formed by the heat sinking structure of FIG. 4;

FIG. 6 shows a partial front sectional view of a heat sinking structure according to a second embodiment of the invention; and

FIG. 7 shows a flow diagram of a third heat path formed by the heat sinking structure of FIG. 6.

### DETAILED DESCRIPTION

A heat sinking structure is described hereinafter for addressing the foregoing problems.

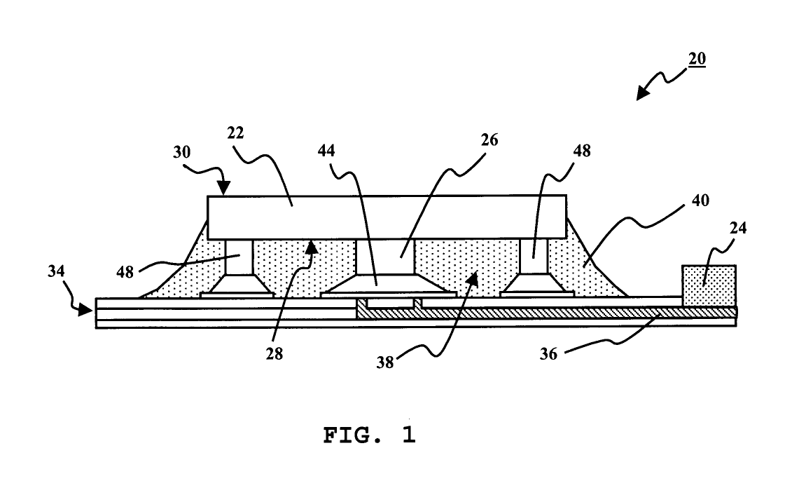

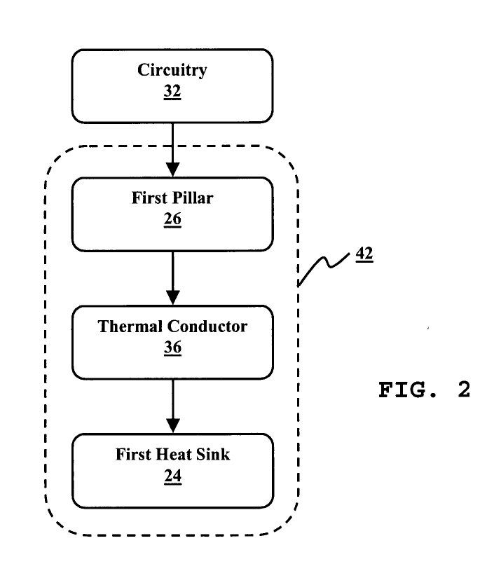

A first embodiment of the invention, a heat sinking structure 20 is described with reference to FIG. 1, which shows a partial front sectional elevation of the heat sinking structure 20, and FIG. 2.

The heat sinking structure 20 comprises a carrier 22, a first heat sink 24 and a first pillar 26. The carrier 22 has a mounting face 28 and a back face 30 which outwardly opposes the mounting face 28. The carrier 22 has a circuitry formed integral therewith and is preferably a semiconductor device, for example a die, with the mounting face 28 being the active side thereof. The circuitry of the carrier 22 generates heat therefrom when being operated.

When heat generated by the circuitry is not effectively dissipated during operation thereof, the operational performance of the circuitry will be adversely affected. In certain situations, the circuitry can even be damaged. The first pillar 26 functions to dissipate heat accumulation within the carrier 22 by effectively conveying heat generated by the circuitry to the first heat sink 24.

The heat sinking structure 20 further comprises a substrate 34. The substrate 24 has a thermal conductor 36 formed integral therewith. Preferably, the thermal conductor 36 forms a portion of a signal-carrying, electrically conductive and thermally conductive pattern formed on the substrate 34.

The first pillar 26 is structurally rigid and extends from the mounting face 28 of the carrier 22 to the substrate 34 for structurally intercoupling and spatially interdisplacing the carrier 22 and the substrate 34 for forming a channel 38 therebetween. The channel 38 between the carrier 22 and the substrate 34 is preferably filled with a filler material 40 for catering to the coefficient of thermal expansion (CTE) mismatch between the carrier 22 and the substrate 34. Alternatively, a non-fill material is usuable for replacing the filler material 40. The first pillar 26 thermally couples the carrier 22 to the thermal conductor 36 of the substrate 34.

As illustrated in FIG. 2, the first pillar 26 of the heat sinking structure 20 forms a first heat path 42 extending initially from the circuitry to the first pillar 26, subsequently from the first pillar 26 to the thermal conductor 36, and finally from the thermal conductor 36 to the first heat sink 24. Therefore, when following the first heat path 42, heat generated by the circuitry is conveyed therefrom to the thermal conductor 36 via the first pillar 26 with the thermal conductor conveying heat received thereby to the first heat sink 24.

Preferably, the transverse cross-section of the first pillar 26 has a circular shape. The transverse cross-section of the first pillar 26 is obtainable along a plane that is perpendicular to the longitudinal axis of the first pillar 26. Alternatively, the transverse cross-section of the first pillar 26 has one of a rectilinear shape, an irregular shape and a geometrically-primitive shape. The first pillar 26 is preferably formed from at least copper. However, the first pillar 26 is formable from at least solder material or the like thermally conductive material. The first pillar 26 is preferably coated with one of oxide, chromium and nickel.

The first pillar 26 comprises a solder portion 44 formed at one extremity thereof for coupling the first pillar 26 to the carrier 22 when subjected to a reflow process. The solder portion 44 of the first pillar 26 has a material composition of one of 63% tin and 37% lead, 99% tin and 1% silver, and 100% tin. Alternatively, the solder portion 42 of the first pillar 26 has a material composition comprising tin and lead, wherein tin concentration is within a range of 60% to 70%. Further alternatively, the solder portion 42 of the first pillar 26 has a lead-free material composition comprising, for example, tin, lead and copper (SAC material).

The first heat sink 24 is air-cooled and disposed spatially remote from the carrier 22. The first heat sink 24 comprises a base and a plurality of fins extending from the base for radiating heat received thereby into air. Alternatively, the first heat sink 24 is formed integral with the substrate 34 and shaped and dimensioned for functioning as a thermal reservoir.

Besides being air-cooled, the first heat sink 24 can alternatively be formed with a fluid-based cooling system (not shown) for dissipating heat received by the first heat sink 24.

The heat sinking structure 20, specifically the first pillar 26 thereof, is preferably used in tandem with pillar connectors 48 in a semiconductor package. Similar to the first pillar 26, each of the pillar connectors 48 is formed extending from the carrier 22 to the substrate 34 and shares the same structural configuration with the first pillar 26. This enables the first pillar 26 and the pillar connectors 48 to be formed together in a single pillar forming process.

The pillar connectors 48 electrically communicate the circuitry of the carrier 22 with signal carrying patterns (not shown) formed on the substrate 34. Due to the substantially uniform transverse cross-sectional shape of the first pillar 26, the transverse cross-sectional dimensions of the first pillar can be increased without affecting the distance between the carrier 22 and the substrate 34, and the distance between adjacent pillar connectors 48, the distance between the first pillar 26 and an adjacent one of the pillar connectors 48.

Additionally, the first pillar 26 is structural rigidity and therefore has good load-bearing capabilities. This enables structural stress created by spatial displacement between the substrate 34 and the carrier 22 to be distributed not only to amongst the pillar connectors 48 but also to the first pillar 26.

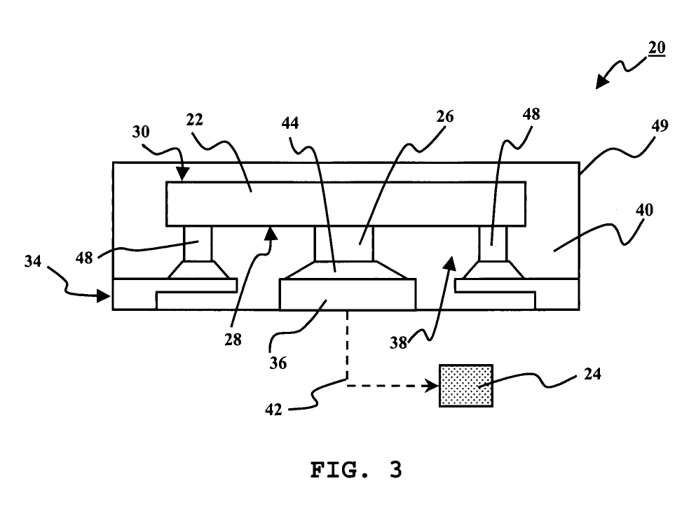

The heat sinking structure 20 is applicable to a variety of semiconductor packages. One example is the quad-flat no-lead (QFN) package 49 as shown FIG. 3 where embedded leads thereof forms the substrate 34 for mounting the carrier 22 thereonto. For the QFN package 49, the filler material 40 is the molding compound used for forming the QFN package encapsulant.

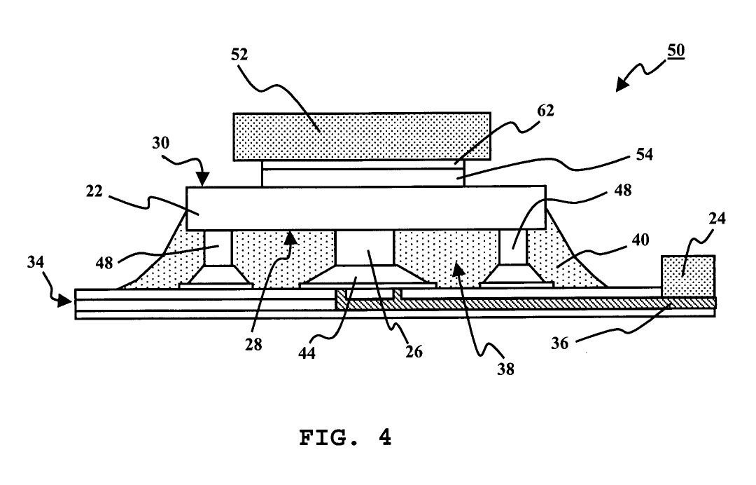

A second embodiment of the invention, a heat sinking structure 50 as seen in FIG. 4 comprises three main elements: a carrier 22, a first heat sink 24 and a first pillar 26. The descriptions in relation to the structural configurations of and positional relationships among the carrier 22, the first heat sink 24, the first pillar 26 and the substrate 34, and the thermal connectivity between the circuitry, the first pillar 26, the thermal conductor 36 and the first heat sink 24 in accordance with the first heat path 42 with reference to FIG. 1 are incorporated herein.

The heat sinking structure 50 further comprises a second heat sink 52 and a second pillar 54 extending from the back face 30 of the carrier 22 to the second heat sink 52. Preferably, the structural shape and material composition of the second pillar 54 is the same as that of the first pillar 26.

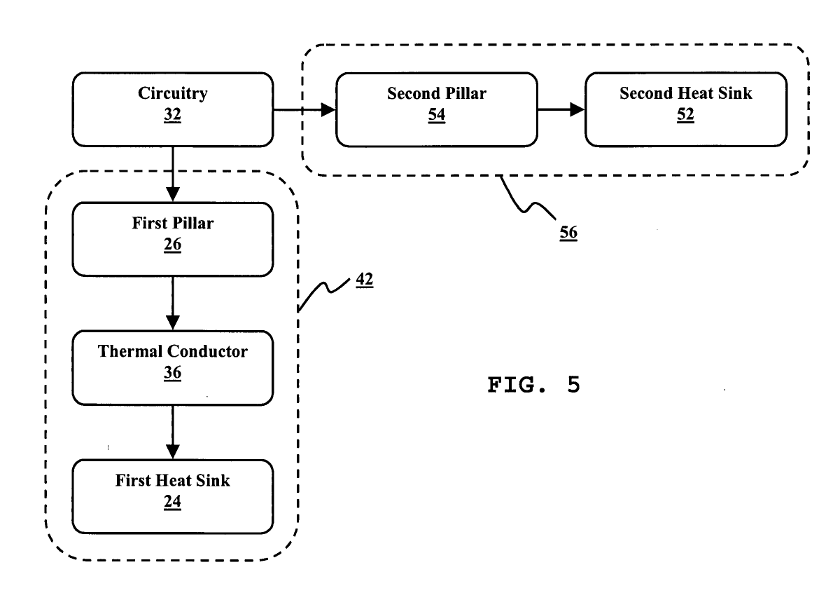

As illustrated in FIG. 5, the second pillar 54 of the heat sinking structure 20 forms a second heat path 56 extending initially from the circuitry to the second pillar 54, and subsequently from the second pillar 54 to the second heat sink 52. Therefore, when following the second heat path 56, heat generated by the circuitry is conveyed therefrom to the second heat sink 52 via the second pillar 54.

Similar to the first heat sink 24, the second heat sink 52 is air-cooled and disposed spatially remote from the carrier 22. When adopting air-based cooling, the second heat sink 52 comprises a base and a plurality of fins extending from the base for radiating heat received thereby into air. A heat spreader 62 preferably interfaces the second pillar 54 and the second heat sink 52 for improving heat transmissibility therebetween.

However, the second heat sink 52 can alternatively be formed for fluid-cooling or for integration with a fluid-based cooling system (not shown).

Additionally, the first heat sink 24 and the second heat sink are further structurally combinable for forming a unitary heat sinking structure.

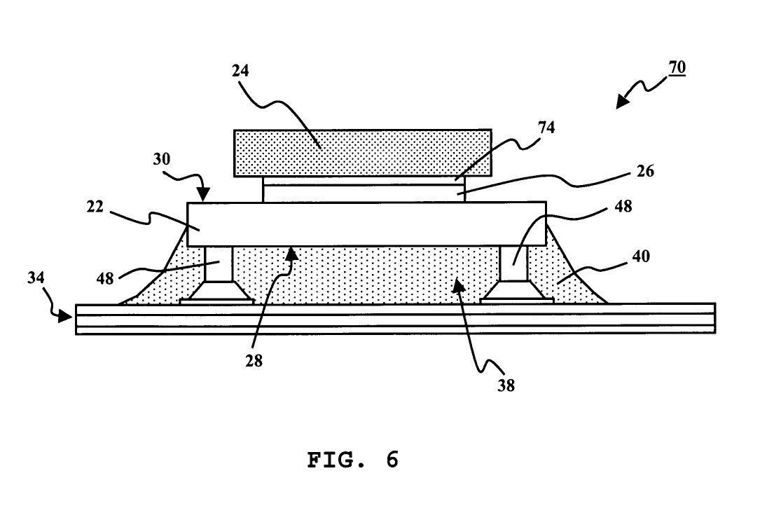

A third embodiment of the invention, a heat sinking structure 70 as seen in FIG. 6 comprises three main elements: a carrier 22, a first heat sink 24 and a first pillar 26. The descriptions in relation to the structural configurations of and positional relationships among the carrier 22, the first heat sink 24, the first pillar 26 and the substrate 34 with reference to FIG. 1 are incorporated herein.

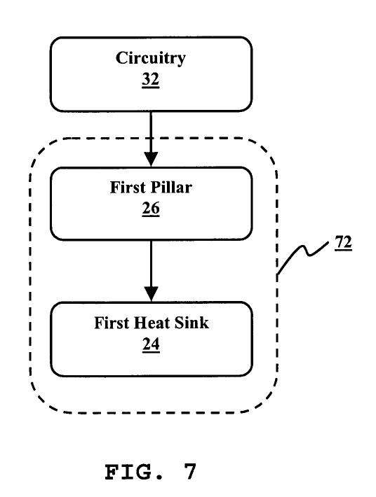

Differing from the first embodiment of the invention, the first pillar 26 extends from the back face 30 of the carrier to the first heat sink 24. The first pillar 26 of the heat sinking structure 70 forms a third heat path 72 extending initially from the circuitry to the first pillar 26, and subsequently from the first pillar 26 to the first heat sink 24 as illustrated in FIG. 7. Therefore, heat generated by the circuitry is conveyed therefrom to the first heat sink 24 via the first pillar 26 following the third heat path 72.

A heat spreader 74 preferably interfaces the first pillar 26 and the first heat sink 24 of the heat sinking structure 70 for improving heat transmissibility therebetween.

In the foregoing manner, a heat sinking structure is described according to three embodiments of the invention for addressing the foregoing disadvantages of conventional heat sinking structures. Although only three embodiments of the invention are disclosed, it will be apparent to one skilled in the art in view of this disclosure that numerous changes and/or modification can be made without departing from the scope and spirit of the invention.

1. A heat sinking structure comprising:
a carrier having a mounting face and a back face outwardly opposing the mounting face, the carrier having a circuitry formed integral therewith, and the circuitry generating heat therefrom when being operated;
a pillar extending from the carrier and being in thermal communication with the circuitry, the pillar being structurally rigid; and
a heat sink being in thermal communication with the pillar,
wherein heat generated by the circuitry is conveyed therefrom to the heat sink via the pillar.

2. The heat sinking structure as in claim 1, the carrier being a semiconductor device and the mounting face being a active side of the semiconductor device.

3. The heat sinking structure as in claim 1, the heat sink being one of fluid-cooled and air-cooled.

4. The heat sinking structure as in claim 1, the heat sink being formed integral with the carrier.

5. The heat sinking structure as in claim 1, the transverse cross-section of the pillar having one of a circular shape, a rectilinear shape, and irregular shape and a geometrically-primitive shape, and the transverse cross-section of the pillar being along a plane formed perpendicular to the longitudinal axis of the pillar.

6. The heat sinking structure as in claim 1, the pillar being formed from at least two conductive materials.

7. The heat sinking structure as in claim 1, the pillar being formed from one of at least solder and at least copper.

8. The heat sinking structure as in claim 1, the pillar being coated with one of oxide, chromium and nickel.

9. The heat sinking structure as in claim 1, further comprising:
a substrate having a thermal conductor formed integral therewith,
wherein the pillar extends from the mounting face of the carrier to the substrate for structurally intercoupling and spatially interdisplacing the semiconductor chip and the substrate, the pillar for thermally coupling the carrier to the thermal conductor of the substrate, and the thermal conductor for conveying heat received from the pillar to the heat sink.

10. The heat sinking structure as in claim 9, the thermal conductor being a thermal conductive pattern formed on the substrate.

11. The heat sinking structure as in claim 9, the pillar comprising:
a solder portion formed on one extremity thereof for coupling the pillar to the carrier.

12. The heat sinking structure as in claim 11, the solder portion of the pillar having a material composition of one of 63% tin and 37% lead, 99% tin and 1% silver, and 100% tin.

13. The heat sinking structure as in claim 11, the solder portion of the pillar having a material composition comprising tin and lead, wherein tin concentration is within a range of 60% to 70%.

14. The heat sinking structure as in claim 11, the solder portion of the pillar having a lead-free material composition.

15. The heat sinking structure as in claim 14, the solder portion of the pillar having a material composition comprising tin, silver and copper.

16. The heat sinking structure as in claim 9, the substrate and the carrier being arrange in a stacked configuration for forming a channel therbetween.

17. The heat sinking structure as in claim 16, the channel being filled with one of a filler material and a non-fill material.

18. The heat sinking structure as in claim 1, the pillar extending from the back face of the carrier for conveying heat generated by the carrier away therefrom.

19. The heat sinking structure as in claim 18, the heat sink comprising:
a base; and
a plurality of fins extending from the base for radiating heat received thereby into air.

20. The heat sinking structure as in claim 18, further comprising:
a heat spreader interfacing the pillar and the second heat sink.

21. A heat sinking structure comprising:
a carrier having a mounting face and a back face outwardly opposing the mounting face, the carrier having a circuitry formed integral therewith, and the circuitry generating heat therefrom when being operated;
a substrate having a thermal conductor formed integral therewith;
a first heat sink being in thermal communication with the thermal conductor of the substrate; and
a first pillar extending from the mounting face of the carrier to the substrate for structurally intercoupling and spatially interdisplacing the carrier and the substrate for forming a channel therebetween, the first pillar for thermally coupling the carrier to the thermal conductor of the substrate,
wherein heat generated by the circuitry is conveyed therefrom to the thermal conductor via the first pillar, and the thermal conductor for conveying heat received thereby to the first heat sink.

22. The heat sinking structure as in claim 21, the carrier being a semiconductor device and the mounting face being a active side of the semiconductor device.

23. The heat sinking structure as in claim 21, the thermal conductor being a thermal conductive pattern formed on the substrate.

24. The heat sinking structure as in claim 21, the transverse cross-section of the pillar having one of a circular shape, a rectilinear shape, and irregular shape and a geometrically-primitive shape, and the transverse cross-section of the pillar being along a plane formed perpendicular to the longitudinal axis of the pillar.

25. The heat sinking structure as in claim 21, the first pillar being formed from at least two conductive materials.

26. The heat sinking structure as in claim 21, the first pillar being formed from one of at least solder and at least copper.

27. The heat sinking structure as in claim 21, the first pillar being coated with one of oxide, chromium and nickel.

28. The heat sinking structure as in claim 21, the first pillar comprising:
a solder portion formed on one extremity thereof for coupling the first pillar to the carrier.

29. The heat sinking structure as in claim 28, the solder portion of the first pillar having a material composition of one of 63% tin and 37% lead, 99% tin and 1% silver, and 100% tin.

30. The heat sinking structure as in claim 28, the solder portion of the first pillar having a material composition comprising tin and lead, wherein tin concentration is within a range of 60% to 70%.

31. The heat sinking structure as in claim 28, the solder portion of the pillar having a lead-free material composition.

32. The heat sinking structure as in claim 31, the solder portion of the pillar having a material composition comprising tin, silver and copper.

33. The heat sinking structure as in claim 21, the first heat sink being formed integral with the substrate.

34. The heat sinking structure as in claim 21, the first heat sink being one of fluid-cooled and air-cooled.

35. The heat sinking structure as in claim 21, the channel being filled with one of a filler material and a non-fill material.

36. The heat sinking structure as in claim 21, further comprising:
a second pillar extending from the back face of the carrier for conveying heat generated by the carrier away therefrom.

37. The heat sinking structure as in claim 36, further comprising:
a second heat sink, the second pillar for thermally communicating the carrier with the heat sink structure for conveying heat generated by the carrier to the second heat sink.

38. The heat sinking structure as in claim 37, the second heat sink comprising:
a base; and
a plurality of fins extending from the base for radiating heat received thereby into air.

39. The heat sinking structure as in claim 37, further comprising:
a heat spreader interfacing the second pillar and the second heat sink.
